(19) United States
(12) Patent Application Publication
(10) Pub. No.: US 2026/0318987 A1
(43) Pub. Date: Oct. 15, 2026

(54) Method and System for Monitoring Chip Open-Circuit Failure of a Multi-Chip IGBT Module

(71) Applicant: SOUTHWEST JIAOTONG UNIVERSITY, Chengdu (CN)

(72) Inventors: Wensheng SONG, Chengdu (CN); Pengcheng XU, Chengdu (CN); Jian CHEN, Chengdu (CN); Haoyang TAN, Chengdu (CN); Kexin YANG, Chengdu (CN); Dong XIE, Chengdu (CN); Chenwei MA, Chengdu (CN); Xinglai GE, Chengdu (CN)

(21) Appl. No.: 19/700,374

(22) Filed: Jun. 8, 2026

Related U.S. Application Data
(63) Continuation of application No. PCT/CN2025/138111, filed on Nov. 27, 2025.

(30) Foreign Application Priority Data
Jan. 24, 2025 (CN) 202510113417.7

(51) Int. Cl. G01R 31/28; G01R 15/04; G01R 19/165

(52) U.S. Cl. CPC G01R 31/2837; G01R 15/04; G01R 19/16528; G01R 19/16576; G01R 31/2839

(57) ABSTRACT

The present disclosure discloses a method and a system for monitoring chip open-circuit failure of a multi-chip IGBT module. The method first determines a health-sensitive parameter for monitoring chip open-circuit failure of the multi-chip IGBT module, then measures a value of the health-sensitive parameter of the multi-chip IGBT module and converts the value into an analog voltage signal, then determines a failure threshold of the analog voltage signal for determining that the multi-chip IGBT module has experienced chip open-circuit failure, and finally compares the measured analog voltage signal with the failure threshold to determine whether the multi-chip IGBT module has experienced chip open-circuit failure. The present disclosure enables monitoring of chip open-circuit failure of a multi-chip IGBT module without opening the package of the multi-chip IGBT module. Because only a gate voltage signal is required to be acquired, fewer factors affect the monitoring result, and measurement is easy to perform.

### TECHNICAL FIELD

The present disclosure relates to the technical field of IGBT module monitoring, and particularly to a method and a system for monitoring chip open-circuit failure of a multi-chip IGBT module.

### BACKGROUND

Insulated gate bipolar transistor (IGBT) modules have been widely used in industrial fields such as rail transit, electric vehicles, and new energy power generation. In high-power power electronic converters, in order to improve the current-carrying capability of a power module, a multi-chip IGBT module composed of a plurality of IGBT chips and diode chips connected in parallel is usually used. Safety and long-term reliability have always been important concerns in the design of power electronic converters. However, surveys have shown that IGBT modules are the components with the highest failure probability in power electronic converters. Among these, bond-wire failure is a main failure mode of IGBT modules. For a multi-chip IGBT module, due to differences in chip characteristics and package layout, bond wires on a chip subjected to relatively high electrothermal stress fail first, and accelerate failure of remaining bond wires on the chip, eventually resulting in chip open-circuit failure. Therefore, introducing condition monitoring technology to identify chip open-circuit failure of a multi-chip IGBT module has become a cost-effective method for improving reliability of a high-power power electronic converter.

There have already been many studies on condition monitoring of chip open-circuit failure of a multi-chip IGBT module. Existing methods may be divided into sensor-based methods and health-sensitive-parameter-based methods. A sensor-based method requires installation of an additional sensor inside the module, significantly increasing monitoring cost and operational risk of the device; in contrast, a health-sensitive-parameter-based method has been widely used because of its fast response speed and low invasiveness. According to different influence mechanisms of bond-wire failure, health-sensitive-parameter-based methods may be further divided into resistance- and inductance-based monitoring methods and capacitance-based monitoring methods. Although a resistance- and inductance-based monitoring method can identify chip open-circuit failure, it has relatively low discrimination and is easily interfered with by partial bond-wire failure. By contrast, a capacitance-based monitoring method can avoid interference from partial bond-wire failure and has relatively high discrimination, and has become the chip open-circuit failure monitoring method currently having the greatest application potential.

At present, capacitance-based monitoring methods mainly include a turn-on delay time t_{don}, a turn-off delay time t_{doff}, a pre-threshold voltage V_{GE(pre-th)}, a gate charge Q_{G}, a crosstalk voltage V_{GEB}, a turn-off voltage change rate dV_{CE}/dt, a gate-voltage fall time t_{gf}, and the like. However, the above methods have disadvantages such as many influencing factors, high invasiveness, susceptibility to interference from a power loop, and difficulty in measurement, and are not conducive to implementing in-situ monitoring of chip open-circuit failure of a multi-chip IGBT module.

### SUMMARY

The present disclosure provides a method and a system for monitoring chip open-circuit failure of a multi-chip IGBT module. The technical problem solved by the present disclosure is that existing methods for monitoring chip open-circuit failure of a multi-chip IGBT module have many influencing factors, high invasiveness, are susceptible to interference, have low discrimination, and are difficult to measure.

In order to solve the above technical problem, the present disclosure provides a method for monitoring chip open-circuit failure of a multi-chip IGBT module, comprising the following steps:
determining a health-sensitive parameter for monitoring chip open-circuit failure of the multi-chip IGBT module, wherein the health-sensitive parameter is related to the number n of effective chip branches in the multi-chip IGBT module and is at least unaffected by a bus voltage and a load current;
measuring a value of the health-sensitive parameter of the multi-chip IGBT module and converting the value into an analog voltage signal V_{PG};
determining a failure threshold V_{REF3} of the analog voltage signal V_{PG} for determining that the multi-chip IGBT module has experienced chip open-circuit failure; and
determining, based on the measured analog voltage signal V_{PG} and the failure threshold V_{REF3}, whether the multi-chip IGBT module has experienced chip open-circuit failure.

Further, the health-sensitive parameter is determined as a gate-voltage pre-charging time t_{PG}, which is a time for a gate voltage of the multi-chip IGBT module to rise from 0 to a preset voltage V_{SET}, and the preset voltage V_{SET} is set below a flat-band voltage at a maximum operating voltage of the multi-chip IGBT module.

Further, by comparing the measured analog voltage signal V_{PG} with the failure threshold V_{REF3}, when V_{PG} is lower than the failure threshold V_{REF3}, it is determined that the multi-chip IGBT module has experienced chip open-circuit failure, and when V_{PG} is higher than the failure threshold V_{REF3}, it is determined that the multi-chip IGBT module has not experienced chip open-circuit failure.

Further, measuring the value of the health-sensitive parameter of the multi-chip IGBT module and converting the value into the analog voltage signal V_{PG} specifically comprises the following steps:
capturing equivalent pulses of a gate voltage signal during turn-on and turn-off processes of the multi-chip IGBT module;
obtaining, based on the captured equivalent pulses during the turn-on and turn-off processes of the multi-chip IGBT module, a digital pulse representing the gate-voltage pre-charging time t_{PG}; and
eliminating a pulse of the turn-off process in the digital pulse representing the gate-voltage pre-charging time t_{PG}, and converting the obtained pulse into the analog voltage signal V_{PG} with an amplitude representing t_{PG}.

Further, capturing the equivalent pulses of the gate voltage signal during the turn-on and turn-off processes of the multi-chip IGBT module specifically comprises the following steps:
performing voltage matching on a collected gate voltage signal of the multi-chip IGBT module through a resistor divider composed of voltage-dividing resistors R₁ and R₂;
raising an output voltage V_{ge} of the resistor divider by a DC voltage E_{C} through a non-inverting adder, to ensure that an output signal V_{gep} of the non-inverting adder falls within an input voltage range allowed by a window comparator;
inputting the output signal V_{gep} of the non-inverting adder into the window comparator, comparing the output signal V_{gep} with input reference voltages V_{REF1} and V_{REF2}, respectively, and outputting corresponding comparison results Vₐ and V_{b}, V_{REF2} being the preset voltage V_{SET}; and
outputting the comparison results Vₐ and V_{b} to a logic sub-circuit through digital isolators U₄ and U₅, respectively, thereby respectively obtaining equivalent pulses during the turn-on and turn-off processes of the multi-chip IGBT module.

Further, obtaining, based on the captured equivalent pulses during the turn-on and turn-off processes of the multi-chip IGBT module, the digital pulse representing the gate-voltage pre-charging time t_{PG} specifically comprises the following steps:
inputting equivalent pulses corresponding to output signals Vₐ and V_{b} of the window comparator into a logic AND gate U₆ to obtain a digital pulse V_{gg} represented by a pulse width;
inputting the equivalent pulse corresponding to the output signal V_{b} of the window comparator into an RC delay circuit, and inputting an output signal of the RC delay circuit together with the equivalent pulse corresponding to V_{b} into a logic AND gate U₇ to obtain an enable signal OE.

Further, eliminating the pulse of the turn-off process in the digital pulse representing the gate-voltage pre-charging time t_{PG} and converting the obtained pulse into the analog voltage signal V_{PG} with the amplitude representing t_{PG} specifically comprises steps of:

inputting an output signal V_{gg} of the logic AND gate U₇ into a signal input terminal of a tri-state buffer U₈, and inputting an output signal OE of the logic AND gate U₆ into an enable terminal of the tri-state buffer U₈; and
inputting an output signal V_{buf} of the tri-state buffer U₈ into an RC integration circuit composed of a resistor R₈ and a capacitor C₃ to obtain the analog voltage signal V_{PG} with the amplitude representing t_{PG}.

Further, determining, based on the measured analog voltage signal V_{PG} and the failure threshold V_{REF3}, whether the multi-chip IGBT module has experienced chip open-circuit failure specifically comprises steps of:
causing the enable signal OE to pass through an RC delay circuit and a logic inverter U₁₀, thereby obtaining a clock signal CLK of a D flip-flop U₁₁;
inputting the output signal V_{PG} and the failure threshold V_{REF3} into a high-speed comparator U₉ for comparison;
inputting an output signal of the high-speed comparator U₉ into a data input terminal of the D flip-flop U₁₁;
outputting, by the D flip-flop U₁₁, a voltage signal V_{dia} characterizing a health state of a chip branch of the multi-chip IGBT module;
when an output voltage V_{dia} is at a low level, the multi-chip IGBT module being in a healthy state; and
when the output voltage V_{dia} is at a high level, the multi-chip IGBT module having experienced chip open-circuit failure.

The present disclosure further provides a system for monitoring chip open-circuit failure of a multi-chip IGBT module, configured to perform the method for monitoring chip open-circuit failure of a multi-chip IGBT module. The key point thereof is that the system comprises a health-sensitive-parameter determination module, a measurement module, a failure-threshold determination module, and a diagnosis module, wherein the health-sensitive-parameter determination module is configured to determine a health-sensitive parameter for monitoring chip open-circuit failure of the multi-chip IGBT module, the measurement module is configured to measure a value of the health-sensitive parameter of the multi-chip IGBT module and convert the value into an analog voltage signal V_{PG}, the failure-threshold determination module is configured to determine a failure threshold V_{REF3} of the analog voltage signal V_{PG} for determining that the multi-chip IGBT module has experienced chip open-circuit failure, and the diagnosis module is configured to determine, based on the measured analog voltage signal V_{PG} and the failure threshold V_{REF3}, whether the multi-chip IGBT module has experienced chip open-circuit failure.

Preferably, the measurement module employs a measurement circuit, and the measurement circuit comprises a signal-processing sub-circuit, a logic sub-circuit, and a signal-conversion sub-circuit;
the signal-processing sub-circuit comprises a resistor divider composed of voltage-dividing resistors R₁ and R₂, a non-inverting adder composed of a high-speed operational amplifier U₁, resistors R₃, R₄, R₅, and R₆, and a capacitor C₁, a window comparator composed of high-speed comparators U₂ and U₃, digital isolators U₄ and U₅, input reference voltages V_{REF1} and V_{REF2}, and a DC voltage E_{C}; the voltage-dividing resistors R₁ and R₂ are coupled in series between a gate G and an auxiliary emitter AE of the multi-chip IGBT module; a midpoint between the voltage-dividing resistors R₁ and R₂ is coupled to a non-inverting input terminal of the high-speed operational amplifier U₁ through the resistor R₄; the DC voltage E_{C} is coupled to the non-inverting input terminal of the high-speed operational amplifier U₁ through the resistor R₅; the resistor R₃ is coupled between an inverting input terminal of the high-speed operational amplifier U₁ and a reference ground; the resistor R₆ and the capacitor C₁ are coupled in parallel between the inverting input terminal and an output terminal of the high-speed operational amplifier U₁; the output terminal of the high-speed operational amplifier U₁ is respectively coupled to a non-inverting input terminal of the high-speed comparator U₂ and an inverting input terminal of the high-speed comparator U₃; the input reference voltages V_{REF1} and V_{REF2} are respectively coupled to an inverting input terminal of the high-speed comparator U₂ and a non-inverting input terminal of the high-speed comparator U₃; and outputs of the high-speed comparator U₂ and the high-speed comparator U₃ are respectively coupled to input terminals of the digital isolators U₄ and U₅;
the logic sub-circuit comprises an RC delay circuit composed of a resistor R₇ and a capacitor C₂ and two logic AND gates U₆ and U₇; the resistor R₇ and the capacitor C₂ are coupled in series between an output terminal of the digital isolator U₄ and a digital reference ground; input terminals of the logic AND gate U₆ are respectively coupled to a midpoint of the RC delay circuit and the output terminal of the digital isolator U₄; and input terminals of the logic AND gate U₇ are respectively coupled to the output terminal of the digital isolator U₄ and an output terminal of the digital isolator U₅; and
the signal-conversion sub-circuit comprises a tri-state buffer U₈ and an RC integration circuit composed of a resistor R₈ and a capacitor C₃; an enable terminal of the tri-state buffer U₈ is coupled to an output terminal of the logic AND gate U₆; a signal input terminal of the tri-state buffer U₈ is coupled to an output terminal of the logic AND gate U₇; the resistor R₈ and the capacitor C₃ are coupled in series between an output terminal of the tri-state buffer U₈ and the digital reference ground; and an output voltage at a series midpoint of the resistor R₈ and the capacitor C₃ is V_{PG} representing the gate-voltage pre-charging time.

In the method and system for monitoring chip open-circuit failure of a multi-chip IGBT module provided by the present disclosure, a health-sensitive parameter for monitoring chip open-circuit failure of the multi-chip IGBT module is first determined, then a value of the health-sensitive parameter of the multi-chip IGBT module is measured and converted into an analog voltage signal V_{PG}, then a failure threshold V_{REF3} of the analog voltage signal V_{PG} for determining that the multi-chip IGBT module has experienced chip open-circuit failure is determined, and finally the measured analog voltage signal V_{PG} is compared with the failure threshold V_{REF3} to determine whether the multi-chip IGBT module has experienced chip open-circuit failure. The present disclosure implements monitoring of chip open-circuit failure of the multi-chip IGBT module without opening the package of the multi-chip IGBT module. In addition, only a gate voltage signal needs to be acquired, so fewer factors affect the monitoring result, measurement is easy to perform, and the disclosed monitoring approach is non-intrusive, can be implemented in a plug-and-play manner or integrated into a drive circuit, facilitates in-situ monitoring of chip open-circuit failure of the multi-chip IGBT module, and has strong practical application value.

### BRIEF DESCRIPTION OF THE DRAWINGS

FIG. 1 is a flowchart of a method for monitoring chip open-circuit failure of a multi-chip IGBT module provided in an embodiment of the present disclosure;

FIG. 2 is a structural and circuit diagram of a multi-chip IGBT module provided in an embodiment of the present disclosure;

FIG. 3 is a waveform diagram of a collector-emitter voltage v_{CE}, a collector current i_{C}, a gate voltage v_{GE}, and a gate current i_{G} during a turn-on process of the multi-chip IGBT module provided in an embodiment of the present disclosure;

FIG. 4 is a circuit diagram of a measurement circuit provided in an embodiment of the present disclosure;

FIG. 5 is an ideal waveform diagram of key nodes of a gate-voltage pre-charging-time measurement circuit of a multi-chip IGBT module provided in an embodiment of the present disclosure;

FIG. 6 is a circuit diagram of a double-pulse test of a multi-chip IGBT module provided in an embodiment of the present disclosure;

FIG. 7 is a circuit diagram of a diagnosis circuit provided in an embodiment of the present disclosure; and

FIG. 8 is a waveform diagram of intermediate nodes and output signals of the diagnosis circuit under different operating conditions, provided in an embodiment of the present disclosure.

### DETAILED DESCRIPTION

The embodiments of the present disclosure are described in detail below with reference to the accompanying drawings. The embodiments are provided merely for purposes of illustration and are not to be construed as limiting the present disclosure. The accompanying drawings are for reference and illustrative purposes only, and do not constitute a limitation on the patent protection scope of the present disclosure, because many changes may be made to the present disclosure without departing from the spirit and scope of the present disclosure.

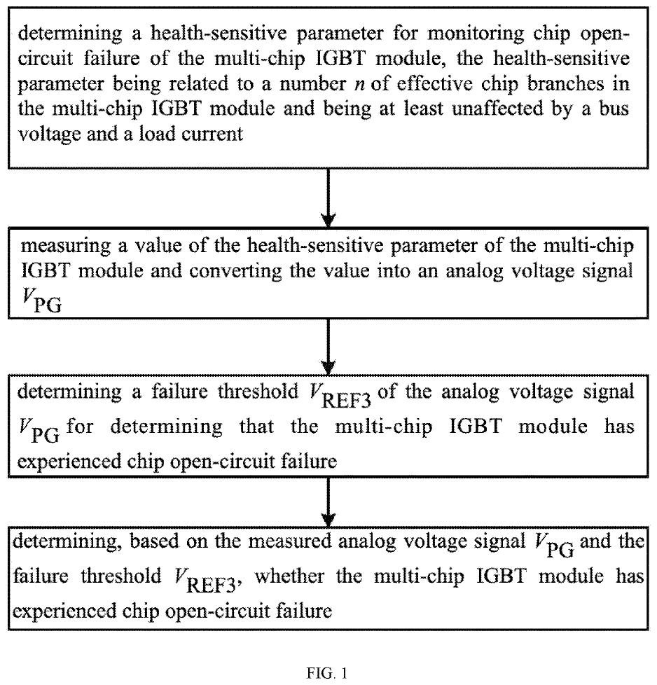

The method for monitoring chip open-circuit failure of a multi-chip IGBT module provided in the embodiments of the present disclosure, as shown in the flowchart of FIG. 1, comprises the following steps:

determining a health-sensitive parameter for monitoring chip open-circuit failure of the multi-chip IGBT module, wherein the health-sensitive parameter is related to a number n of effective chip branches in the multi-chip IGBT module and is at least unaffected by a bus voltage and a load current;
measuring a value of the health-sensitive parameter of the multi-chip IGBT module and converting the value into an analog voltage signal V_{PG};
determining a failure threshold V_{REF3} of the analog voltage signal V_{PG} for determining that the multi-chip IGBT module has experienced chip open-circuit failure; and
determining, based on the measured analog voltage signal V_{PG} and the failure threshold V_{REF3}, whether the multi-chip IGBT module has experienced chip open-circuit failure.

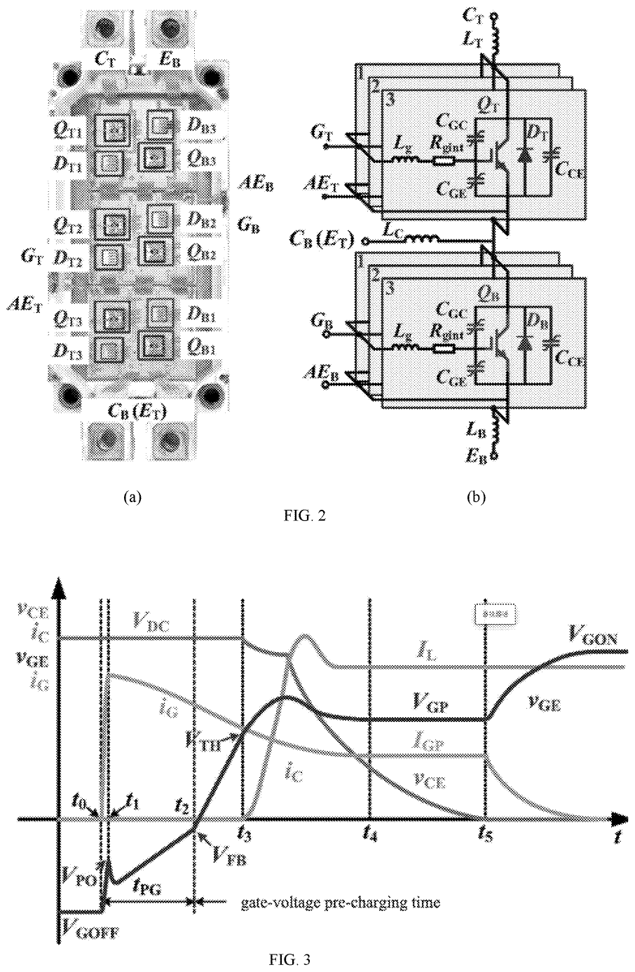

A structure and circuit of a specific multi-chip IGBT module are shown in FIG. 2. The module is an FF150R12ME3G soldered IGBT module. FIG. 2(a) shows an internal structure of the FF150R12ME3G soldered IGBT module, and FIG. 2(b) shows an equivalent circuit of the FF150R12ME3G soldered IGBT module. The FF150R12ME3G soldered IGBT module includes two switches connected in series to form a half-bridge structure. Each switch is composed of three chip branches, and each chip branch is composed of one IGBT chip and one FWD chip. In FIG. 2(a), meanings of first capital letters of parameter symbols are as follows: Q represents an IGBT chip, D represents a diode chip, G represents a gate, AE represents an auxiliary emitter, C represents a collector, and E represents an emitter. Meanings of first subscripts of the parameter symbols are as follows: T represents a top portion, and B represents a bottom portion. A second subscript, if present, designates a chip number. In FIG. 2(b), R_{gint}, L_{g}, C_{GC}, C_{GE}, and C_{CE} respectively represent an internal gate resistance, a parasitic inductance of a gate loop, a gate-collector capacitance, a gate-emitter capacitance, and a collector-emitter capacitance of each chip branch. L_{T} is a parasitic inductance of an upper-switch power terminal, L_{C} is a parasitic inductance of a midpoint power terminal, and L_{B} is a parasitic inductance of a lower-switch power terminal.

A waveform diagram of a collector-emitter voltage v_{CE}, a collector current i_{C}, a gate voltage v_{GE}, and a gate current i_{G} during a turn-on process of the multi-chip IGBT module is shown in FIG. 3, in which V_{DC}, I_{L}, V_{PO}, V_{FB}, V_{TH}, V_{GP}, V_{GON}, V_{GOFF}, and I_{GP} respectively represent a DC bus voltage, a load current, a gate spike voltage, a flat-band voltage, a threshold voltage, a Miller plateau voltage, a turn-on gate voltage, a turn-off gate voltage, and a Miller plateau current. According to characteristics of the collector current, the present disclosure divides the turn-on process of the multi-chip IGBT module into two stages:
(1) pre-charging stage (t₀-t₃): in this stage, a gate control signal is inverted from 0 to 1, and the gate voltage v_{GE} starts to rise at time to and rises to V_{PO}, V_{FB}, and V_{TH} at times t₁, t₂, and t₃, respectively. In the pre-charging stage, a conductive channel has not yet been formally formed, and the collector current i_{C} and the collector-emitter voltage v_{CE} do not change significantly.
(2) rapid turn-on stage (t>t₃): when v_{GE} exceeds the threshold voltage V_{TH}, the conductive channel is formally formed, the multi-chip IGBT module formally enters the rapid turn-on stage, the collector current i_{C} starts to rise rapidly, and the collector-emitter voltage v_{CE} starts to decrease rapidly.

An expression of the gate voltage in the pre-charging stage is:

$${v}_{GE} = {V}_{GON} - \frac{{R}_{gext} ( {V}_{GON} - {V}_{GOFF} )}{{R}_{gext} + {R}_{gaint} / n} {e}^{- t / ( {nR}_{gext + {R}_{gint}} ) {C}_{GE}} \qquad ( 1 )$$

where n is the number of effective chip branches in the multi-chip IGBT module, R_{gint} is an internal gate resistance of a single chip branch, R_{gext} is an external gate resistance, R_{gint} is the internal gate resistance of the single chip branch, C_{GE} is a gate-emitter capacitance of a single chip, V_{GON} is a turn-on gate voltage, V_{GOFF} is a turn-off gate voltage, V_{SET} is a voltage defining an ending time of t_{PG}, t represents time, and e represents a natural base.

A time for the gate voltage to rise from 0 to the preset voltage V_{SET} is defined as the pre-charging time t_{PG}, and a relationship between the pre-charging time t_{PG} and the number n of chip branches connected in parallel may be expressed as:

$${t}_{PG} = ( {nR}_{gext} + {R}_{gint} ) {C}_{GE} ln \frac{( {V}_{GON} - {V}_{GOFF} ) {R}_{gext}}{( {V}_{GON} - {V}_{SET} ) ( {R}_{gext} + {R}_{gint} / n )} \qquad ( 2 )$$

After chip open-circuit failure occurs, the number n of chip branches connected in parallel inside the module decreases, and the gate-voltage pre-charging time t_{PG} decreases. Therefore, t_{PG} may be used as a health-sensitive parameter for monitoring chip open-circuit failure.

Further, a relationship of t_{PG} with a bus voltage, a load current, and a junction temperature needs to be analyzed.
(1) Relationship between t_{PG} and the bus voltage V_{DC}: an expression of the gate-emitter capacitance C_{GE} during a switching process is:

$${C}_{GE} = \{ \begin{matrix}{C}_{OXD} & {t}_{0} < t < {t}_{2} \\ \frac{{C}_{OXD} {C}_{dep}}{{C}_{OXD} + {C}_{dep}} & t > {t}_{2}\end{matrix} \qquad ( 3 )$$

where C_{OXD} is a gate oxide capacitance and is unrelated to the bus voltage. C_{dep} is a depletion-layer capacitance and is inversely proportional to the bus voltage. Therefore, by setting an ending voltage V_{SET} of t_{PG} below the flat-band voltage V_{FB}, an influence of variation in the bus voltage can be eliminated. Further, the flat-band voltage V_{FB} is affected by the bus voltage. Due to a short-channel effect, V_{FB} decreases as the bus voltage increases. Therefore, the present disclosure sets V_{SET} below the flat-band voltage at the maximum operating voltage of the multi-chip IGBT module, thereby eliminating the influence of variation in the bus voltage.
(2) Relationship between t_{PG} and the load current I_{L}: in the pre-charging stage, a conductive channel in an IGBT gate region has not yet been formally formed. Regardless of how the load current changes, a collector current i_{C} flowing through the multi-chip IGBT module is always 0. Therefore, t_{PG} is unrelated to the load current I_{L}.
(3) Relationship between t_{PG} and the junction temperature Tⱼ: in the expression of t_{PG}, only R_{gint} is affected by variation in the junction temperature. By differentiating t_{PG} with respect to R_{gint}, the following may be obtained:

$$\frac{{dt}_{PG}}{{dR}_{gint}} = {C}_{GE} ( ln \frac{( {V}_{GON} - {V}_{GOFF} ) {R}_{gext}}{( {V}_{GON} - {V}_{SET} ) ( {R}_{gext} + {R}_{gint} / n )} - 1 ) \qquad ( 4 )$$

where a temperature sensitivity of R_{gint} is very small and is only 1-2 mV/° C. In addition, presence of the external gate resistance R_{gext} further suppresses an influence of variation in R_{gint}. Therefore, variation in the junction temperature has only a slight influence on t_{PG}.

Therefore, in this embodiment, the health-sensitive parameter is determined as the gate-voltage pre-charging time t_{PG} of the multi-chip IGBT module. The health-sensitive parameter may also be set as another parameter, but the parameter needs to satisfy that the parameter is related to the number n of effective chip branches in the multi-chip IGBT module and is at least unaffected by the bus voltage and the load current.

In order to effectively measure the value of the health-sensitive parameter of the multi-chip IGBT module, i.e., the gate-voltage pre-charging time t_{PG}, and convert the value into an analog voltage signal V_{PG}, this embodiment specifically adopts the following steps:
capturing equivalent pulses of a gate voltage signal during turn-on and turn-off processes of the multi-chip IGBT module;
obtaining, based on the captured equivalent pulses during the turn-on and turn-off processes of the multi-chip IGBT module, a digital pulse representing the gate-voltage pre-charging time t_{PG}; and
eliminating a pulse of the turn-off process in the digital pulse representing the gate-voltage pre-charging time t_{PG}, and converting the obtained pulse into the analog voltage signal V_{PG} with an amplitude representing t_{PG}.

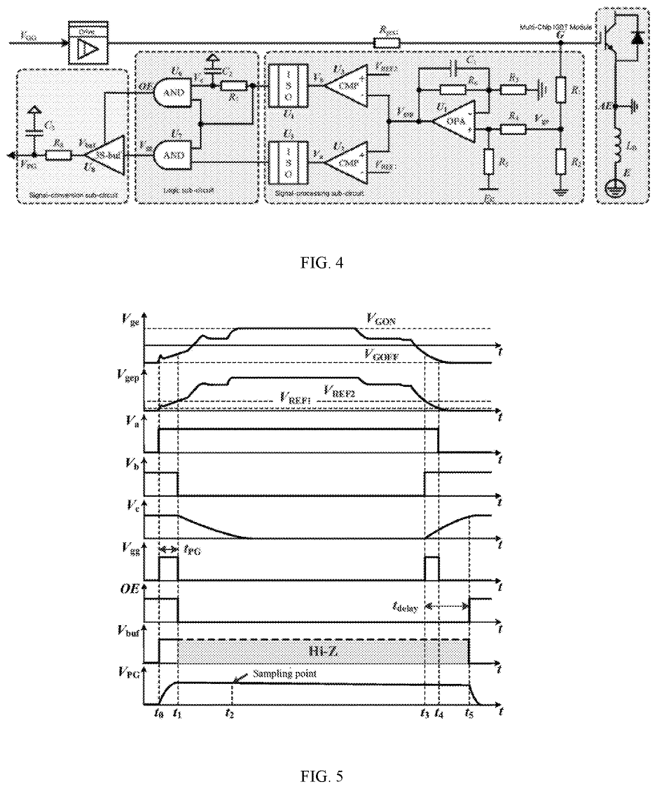

In this embodiment, a measurement circuit is designed to implement the above three steps. As shown in the circuit diagram of the measurement circuit provided in FIG. 4, the measurement circuit specifically comprises a signal-processing sub-circuit, a logic sub-circuit, and a signal-conversion sub-circuit, respectively configured to implement the above three steps.

A main function of the signal-processing sub-circuit is to capture a starting time and an ending time of t_{PG}. As shown in FIG. 4, the signal-processing sub-circuit comprises a resistor divider composed of voltage-dividing resistors R₁ and R₂, a non-inverting adder composed of a high-speed operational amplifier (OPA) U₁, resistors R₃, R₄, R₅, and R₆, and a capacitor C₁, a window comparator composed of high-speed comparators (CMP) U₂ and U₃, digital isolators (ISO) U₄ and U₅, input reference voltages V_{REF1} and V_{REF2} (V_{REF2} representing V_{SET}), and a DC voltage E_{C}. The voltage-dividing resistors R₁ and R₂ are coupled in series between a gate G and an auxiliary emitter AE of the multi-chip IGBT module. A midpoint between the voltage-dividing resistors R₁ and R₂ is coupled to a non-inverting input terminal of the high-speed operational amplifier U₁ through the resistor R₄. The DC voltage E_{C} is coupled to a non-inverting input terminal of the high-speed operational amplifier U₁ through the resistor R₅. The resistor R₃ is coupled between an inverting input terminal of the high-speed operational amplifier U₁ and a reference ground. The resistor R₆ and the capacitor C₁ are coupled in parallel between the inverting input terminal and an output terminal of the high-speed operational amplifier U₁. The output terminal of the high-speed operational amplifier U₁ is respectively coupled to a non-inverting input terminal of the high-speed comparator U₂ and an inverting input terminal of the high-speed comparator U₃. The input reference voltages V_{REF1} and V_{REF2} are respectively coupled to an inverting input terminal of the high-speed comparator U₂ and a non-inverting input terminal of the high-speed comparator U₃. Outputs of the high-speed comparator U₂ and the high-speed comparator U₃ are respectively coupled to input terminals of the digital isolators U₄ and U₅.

A working process of the signal-processing sub-circuit is as follows:
performing voltage matching on a collected gate voltage signal of the multi-chip IGBT module through the resistor divider composed of the voltage-dividing resistors R₁ and R₂;
raising an output voltage V_{ge} of the resistor divider by a DC voltage E_{C} through the non-inverting adder, to ensure that an output signal V_{gep} of the non-inverting adder is within an input voltage range allowed by the window comparator and suppress interference of a gate spike voltage V_{PO};
inputting the output signal V_{gep} of the non-inverting adder into the window comparator, comparing the output signal with the input reference voltages V_{REF1} and V_{REF2}, respectively, and outputting corresponding comparison results Vₐ and V_{b}; and
outputting the comparison results Vₐ and V_{b} to the logic sub-circuit through the digital isolators U₄ and U₅, respectively, thereby respectively obtaining equivalent pulses during turn-on and turn-off processes of the multi-chip IGBT module.

It should be pointed out that the capacitor C₁ is connected in parallel in a feedback loop of the non-inverting adder, and a main function thereof is to perform phase compensation and form a low-pass filter so as to suppress interference of the gate spike voltage V_{PO} with measurement. A design principle of a capacitance value thereof is:

$${C}_{1} = \frac{2 {\sqrt{2 t}}_{r\_PG}}{7 π {R}_{6}} \qquad ( 5 )$$

where t_{r_PG} is a duration of the gate-voltage pre-charging stage.

A main function of the logic sub-circuit is to convert comparison results of the window comparator into a digital pulse represented by a pulse width representing t_{PG}, and generate an enable signal for the signal-conversion sub-circuit. As shown in FIG. 4, the logic sub-circuit comprises an RC delay circuit composed of a resistor R₇ and a capacitor C₂ and two logic AND gates (AND) U₆ and U₇. The resistor R₇ and the capacitor C₂ are coupled in series between an output terminal of the digital isolator U₄ and a digital reference ground. Input terminals of the logic AND gate U₆ are respectively coupled to a midpoint of the RC delay circuit and the output terminal of the digital isolator U₄. Input terminals of the logic AND gate U₇ are respectively coupled to the output terminal of the digital isolator U₄ and the output terminal of the digital isolator U₅.

A working process of the logic sub-circuit is as follows:
inputting equivalent pulses corresponding to output signals Vₐ and V_{b} of the window comparator into the logic AND gate U₆ to obtain a digital pulse V_{gg} represented by a pulse width; and
inputting the equivalent pulse corresponding to the output signal V_{b} of the window comparator into the RC delay circuit, and inputting an output signal of the RC delay circuit together with the equivalent pulse corresponding to V into the logic AND gate U₇ to obtain an enable signal OE.

A main function of the signal-conversion sub-circuit is to eliminate a pulse of a turn-off process and convert t_{PG} into an analog voltage signal V_{PG}. As shown in FIG. 4, the signal-conversion sub-circuit comprises a tri-state buffer (3S-buf) U₈ and an RC integration circuit composed of a resistor R₈ and a capacitor C₃. An enable terminal of the tri-state buffer U₈ is coupled to an output terminal of the logic AND gate U₆. A signal input terminal of the tri-state buffer U₈ is coupled to an output terminal of the logic AND gate U₇. The resistor R₈ and the capacitor C₃ are coupled in series between an output terminal of the tri-state buffer U₈ and a digital reference ground. An output voltage at a series midpoint of the resistor R₈ and the capacitor C₃ is V_{PG} representing the gate-voltage pre-charging time.

A working process of the signal-conversion sub-circuit is as follows:
inputting an output signal V_{gg} of the logic AND gate U₆ into a signal input terminal of the tri-state buffer U₈, and inputting an output signal OE of the logic AND gate U₇ into an enable terminal of the tri-state buffer U₈; and
inputting an output signal V_{buf} of the tri-state buffer U₈ into the RC integration circuit composed of the resistor R₈ and the capacitor C₃ to obtain the analog voltage signal V_{PG} with an amplitude representing t_{PG}.

A design principle of the RC integration circuit in the signal-conversion sub-circuit is based on an input voltage range allowed by an ADC of a microprocessor. In the present disclosure, taking a microprocessor having an allowed input voltage range of 3.3 V as an example, under a condition of ensuring a 20% safety margin, a value selection principle of the RC integration circuit is:

$${t}_{PG} = \frac{3}{4} {R}_{8} {C}_{3} \qquad ( 6 )$$

FIG. 5 is an ideal waveform diagram of key nodes of a gate-voltage pre-charging-time measurement circuit of a multi-chip IGBT module, in which tdelay is a delay time introduced by the RC delay circuit in the logic sub-circuit, and HI-Z is a high-impedance state. After signal processing and the logic sub-circuit, the gate voltage of the multi-chip IGBT module becomes a digital pulse V_{gg} having a pulse width of t_{PG} and an enable signal OE. Within a range of t_{PG} (t₀-t₁), OE is at a high level, and an output signal V_{buf} of U₈ is inverted from a low level to a high level at time to and starts charging the capacitor C₃, such that a voltage V_{PG} on C₃ starts to rise exponentially from 0. During a stage of t₁-t₅, OE is inverted to a low level, V_{buf} is in a high-impedance state, and V_{PG} remains at a value at time t₁. This state continues until time t₅, when OE is again inverted to a high level, and V_{PG} starts to discharge to 0. It should be pointed out that the stage of t₁-t₅ includes the turn-off process of the multi-chip IGBT module, thereby eliminating an influence of a digital pulse of the turn-off process.

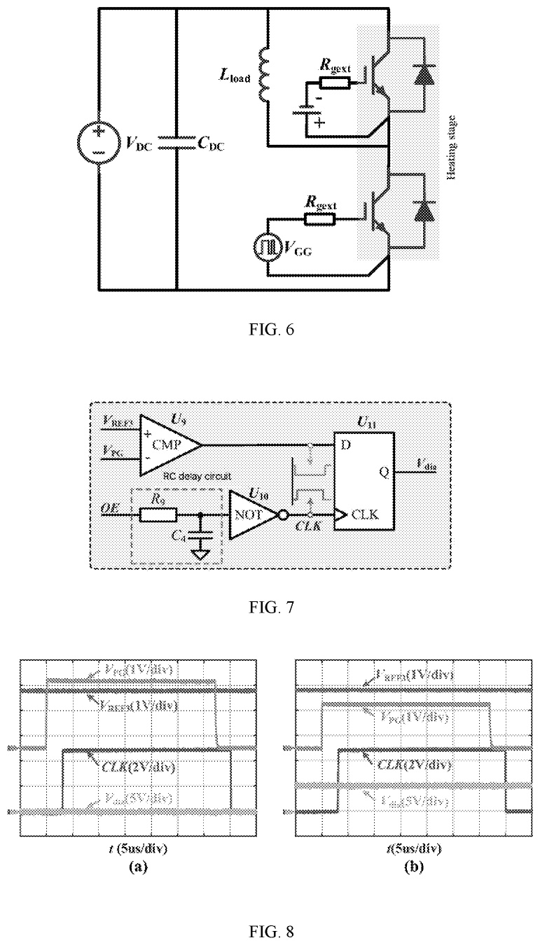

In this embodiment, by building a double-pulse test circuit of the multi-chip IGBT module as shown in FIG. 6, full-operating-condition tests are respectively performed on a multi-chip IGBT module in a healthy state and a multi-chip IGBT module in which one chip branch has experienced open-circuit failure, V_{PG} under all operating conditions is recorded, and a failure threshold V_{REF3} for determining that the multi-chip IGBT module has experienced chip open-circuit failure is set according to experimental results. In FIG. 6, an upper IGBT device is always in an off state, a lower IGBT device is in a normal switching state, a load inductor L_{load} is connected in parallel across two ends of the upper IGBT device, V_{DC} is a DC power supply voltage, C_{DC} is a DC-side support capacitor, R_{gext} is an external gate resistance, and V_{GG} is a gate control signal.

In a specific experiment, in the embodiments of the present disclosure, the multi-chip IGBT module FF150R12ME3G having three chip branches connected in parallel as shown in FIG. 2 is tested under a healthy operating condition and an open-circuit failure operating condition in which one chip branch has experienced open-circuit failure, and an experimental circuit is constructed according to FIG. 6. Relevant parameter settings of the experimental circuit are shown in Table 1 below. Chip open-circuit failure of the multi-chip IGBT module is simulated by cutting all emitter bond wires on QB1 shown in FIG. 2.

TABLE 1

| Parameter | Value/Model |
|---|---|
| Multi-chip IGBT module | FF150R12ME3G |
| Number of chip branches connected in parallel | 3 |
| Turn-on gate voltage V_{GBON} | 15 V |
| Turn-off gate voltage V_{GBOFF} | −8 V |
| Load inductance L_{load} | 0.5 mH |
| DC bus capacitor C_{DC} | 1 mF |
| External gate resistance R_{g ext} | 10 Ω |

In some embodiments, under the healthy operating condition and the open-circuit failure operating condition, V_{PG} is unrelated to the bus voltage V_{DC}, and V_{PG} under the two operating conditions remains substantially unchanged. Under the healthy operating condition, an average value of V_{PG} is about 2.669 V, a maximum value is 2.675 V, and a minimum value is 2.655 V. Under the open-circuit failure operating condition, an average value of V_{PG} is about 1.733 V, a maximum value is 1.738 V, and a minimum value is 1.729 V.

In some embodiments, under the healthy operating condition and the open-circuit failure operating condition, V_{PG} is unrelated to the load current I_{L}, and V_{PG} under the two operating conditions remains substantially unchanged. Under the healthy operating condition, an average value of V_{PG} is about 2.672 V, a maximum value is 2.675 V, and a minimum value is 2.671 V. Under the open-circuit failure operating condition, an average value of V_{PG} is about 1.732 V, a maximum value is 1.735 V, and a minimum value is 1.729 V.

In some embodiments, under the healthy operating condition and the open-circuit failure operating condition, VPG has little correlation with the junction temperature Tⱼ, and variation of V_{PG} under the two operating conditions is small. Under the healthy operating condition, an average value of V_{PG} is about 2.675 V, a maximum value is 2.707 V, and a minimum value is 2.643 V. Under the open-circuit failure operating condition, an average value of V_{PG} is about 1.729 V, a maximum value is 1.783 V, and a minimum value is 1.673 V.

It can be seen that V_{PG} under the two operating conditions is relatively stable, and V_{PG} under the two operating conditions has an obvious difference. By using a rounding method, under different bus voltages V_{DC}, different load currents I_{L}, and different junction temperatures Tⱼ, V_{PG} under the healthy operating condition is 2.7 V (V_{He}), and V_{PG} under the open-circuit failure operating condition is 1.7 V (V_{Fa}). In order to accurately distinguish the two operating conditions, in this embodiment, the failure threshold V_{REF3} for determining that the multi-chip IGBT module has experienced chip open-circuit failure is set as:

V_{REF3}∈[V_{Fa}+α(V_{He}−V_{Fa}),V_{Fa}−α(V_{He}−V_{Fa})] (7)

A value of a coefficient factor α needs to satisfy that V_{Fa}+α(V_{He}−V_{Fa}) is greater than a maximum value of V_{PG} under all open-circuit failure operating conditions, and V_{Fa}−α(V_{He}−V_{Fa}) is less than a minimum value of V_{PG} under all healthy operating conditions.

In order to accurately distinguish the healthy operating condition from the open-circuit failure operating condition, a should not be too small. In this embodiment, a is selected within (0.1, 0.5], and finally a is determined to be 0.4. Accordingly, the failure threshold V_{REF3} is selected from [2.1, 2.3] V, and in this example, the failure threshold V_{REF3} is selected to be 2.3 V.

By comparing the measured analog voltage signal V_{PG} with the failure threshold V_{REF3}, when V_{PG} is lower than the failure threshold V_{REF3}, it is determined that the multi-chip IGBT module has experienced chip open-circuit failure, and when V_{PG} is higher than the failure threshold V_{REF3}, it is determined that the multi-chip IGBT module has not experienced chip open-circuit failure.

In addition to testing the multi-chip IGBT module in which one chip branch has experienced open-circuit failure, the multi-chip IGBT module in which two or more chip branches have experienced open-circuit failure may also be tested. By setting, under operating conditions in which one chip branch, two chip branches, to n−1 chip branches have experienced open-circuit failure, failure thresholds sufficient to distinguish among n operating conditions including the healthy operating condition and open-circuit failure operating conditions in which one chip branch, two chip branches, to n−1 chip branches have experienced open-circuit failure, a number of chip branches that have experienced open-circuit failure may be obtained.

In order to compare the measured analog voltage signal V_{PG} with the failure threshold V_{REF3} and obtain a diagnosis result, the embodiments of the present disclosure design a diagnosis circuit, as shown in the circuit diagram of FIG. 7. The diagnosis circuit mainly comprises a high-speed comparator U₉, an RC delay circuit composed of a resistor R₉ and a capacitor C₄, a logic inverter U₁₀, a D flip-flop U₁₁, and an input reference voltage V_{REF3} (failure threshold). Input terminals of the high-speed comparator U₉ are respectively coupled to the input reference voltage V_{REF3} and the output V_{PG} of the measurement circuit. The resistor R₉ and the capacitor C₄ are coupled in series between an output terminal of the logic AND gate U₆ and a digital reference ground. An input terminal of the logic inverter U₁₀ is coupled to a series midpoint of the resistor R₉ and the capacitor C₄. Input terminals of the D flip-flop U₁₁ are respectively coupled to an output terminal of the high-speed comparator U₉ and an output terminal of the logic inverter U₁₀. An output terminal of the D flip-flop U₁₁ is a voltage signal V_{dia} characterizing a health state of a chip branch of the multi-chip IGBT module.

A working process of the diagnosis circuit is as follows:
causing the enable signal OE to pass through the RC delay circuit and the logic inverter U₁₀, thereby obtaining a clock signal CLK of the D flip-flop U₁₁;
inputting the output signal V_{PG} of the measurement circuit and the input reference voltage V_{REF3} into the high-speed comparator U₉ for comparison;
inputting an output signal of the high-speed comparator U₉ into a data input terminal of the D flip-flop U₁₁; and
outputting, by the D flip-flop U₁₁, the voltage signal V_{dia} characterizing the health state of the chip branch of the multi-chip IGBT module.

When an output voltage V_{dia} of the diagnosis circuit is at a low level, the multi-chip IGBT module is in a healthy state.

When the output voltage V_{dia} of the diagnosis circuit is at a high level, the multi-chip IGBT module has experienced chip open-circuit failure.

FIG. 8 is a waveform diagram of intermediate nodes and output signals of the diagnosis circuit under different operating conditions, in which (a) is a healthy operating condition, and (b) is an open-circuit failure operating condition. It can be seen from FIG. 8 that, when the multi-chip IGBT module has not experienced chip open-circuit failure, the output signal V_{dia} of the D flip-flop U₁₁ is at a low level, and when the multi-chip IGBT module has experienced chip open-circuit failure, the output signal V_{dia} of the D flip-flop U₁₁ is at a high level, which verifies effectiveness of the diagnosis circuit.

It should also be noted that the above measurement circuit and diagnosis circuit are only preferred implementation modes, and other circuits and implementation modes capable of implementing the same functions may also be used.

The embodiments of the present disclosure further provide a system for monitoring chip open-circuit failure of a multi-chip IGBT module, which applies the above method for monitoring chip open-circuit failure of a multi-chip IGBT module. The system comprises a health-sensitive-parameter determination module, a measurement module, a failure-threshold determination module, and a diagnosis module. The health-sensitive-parameter determination module is configured to determine a health-sensitive parameter for monitoring chip open-circuit failure of the multi-chip IGBT module, the measurement module is configured to measure a value of the health-sensitive parameter of the multi-chip IGBT module and convert the value into an analog voltage signal V_{PG}, the failure-threshold determination module is configured to determine a failure threshold V_{REF3} of the analog voltage signal V_{PG} for determining that the multi-chip IGBT module has experienced chip open-circuit failure, and the diagnosis module is configured to determine, based on the measured analog voltage signal V_{PG} and the failure threshold V_{REF3}, whether the multi-chip IGBT module has experienced chip open-circuit failure. These modules are electronic modules capable of implementing corresponding functions, and the measurement module and the diagnosis module may employ the above measurement circuit and diagnosis circuit.

In summary, in the method and system for monitoring chip open-circuit failure of a multi-chip IGBT module provided by the embodiments of the present disclosure, a health-sensitive parameter for monitoring chip open-circuit failure of the multi-chip IGBT module is first determined, then a value of the health-sensitive parameter of the multi-chip IGBT module is measured and converted into an analog voltage signal V_{PG}, then a failure threshold V_{REF3} of the analog voltage signal V_{PG} for determining that the multi-chip IGBT module has experienced chip open-circuit failure is determined, and finally the measured analog voltage signal V_{PG} is compared with the failure threshold V_{REF3} to determine whether the multi-chip IGBT module has experienced chip open-circuit failure. The present disclosure implements monitoring of chip open-circuit failure of the multi-chip IGBT module without opening a package of the multi-chip IGBT module. In addition, only a gate voltage signal needs to be acquired, so fewer factors affect the monitoring result, measurement is easy to perform, the method is non-intrusive, can be implemented in a plug-and-play manner or integrated into a drive circuit, facilitates in-situ monitoring of chip open-circuit failure of the multi-chip IGBT module, and has strong practical application value.

The above embodiments are preferred implementation modes of the present disclosure, but the implementation modes of the present disclosure are not limited by the above embodiments. Any other changes, modifications, substitutions, combinations, and simplifications made without departing from the spirit, essence, and principle of the present disclosure shall be construed as equivalent replacements and shall fall within the protection scope of the present disclosure.

1. A method for monitoring chip open-circuit failure of a multi-chip IGBT module, comprising:
determining a health-sensitive parameter for monitoring chip open-circuit failure of the multi-chip IGBT module, the health-sensitive parameter being related to a number n of effective chip branches in the multi-chip IGBT module and being at least unaffected by a bus voltage and a load current, wherein the health-sensitive parameter is determined as a gate-voltage pre-charging time t_{PG}, which is a time for a gate voltage of the multi-chip IGBT module to rise from 0 to a preset voltage V_{SET}, and the preset voltage V_{SET} is set below a flat-band voltage at a maximum operating voltage of the multi-chip IGBT module;
measuring a value of the health-sensitive parameter of the multi-chip IGBT module and converting the value into an analog voltage signal V_{PG};
determining a failure threshold V_{REF3} of the analog voltage signal V_{PG} for determining that the multi-chip IGBT module has experienced chip open-circuit failure; and
determining, based on the measured analog voltage signal V_{PG} and the failure threshold V_{REF3}, whether the multi-chip IGBT module has experienced chip open-circuit failure.

2. The method for monitoring chip open-circuit failure of a multi-chip IGBT module of claim 1, wherein by comparing the measured analog voltage signal V_{PG} with the failure threshold V_{REF3}, when V_{PG} is lower than the failure threshold V_{REF3}, it is determined that the multi-chip IGBT module has experienced chip open-circuit failure, and when V_{PG} is higher than the failure threshold V_{REF3}, it is determined that the multi-chip IGBT module has not experienced chip open-circuit failure.

3. The method for monitoring chip open-circuit failure of a multi-chip IGBT module of claim 2, wherein measuring the value of the health-sensitive parameter of the multi-chip IGBT module and converting the value into the analog voltage signal V_{PG} specifically comprises steps of:
capturing equivalent pulses of a gate voltage signal during turn-on and turn-off processes of the multi-chip IGBT module;
obtaining, based on the captured equivalent pulses during the turn-on and turn-off processes of the multi-chip IGBT module, a digital pulse representing the gate-voltage pre-charging time t_{PG}; and
eliminating a pulse of the turn-off process in the digital pulse representing the gate-voltage pre-charging time t_{PG}, and converting the obtained pulse into the analog voltage signal V_{PG} with an amplitude representing t_{PG}.

4. The method for monitoring chip open-circuit failure of a multi-chip IGBT module of claim 3, wherein capturing the equivalent pulses of the gate voltage signal during the turn-on and turn-off processes of the multi-chip IGBT module comprises:
performing voltage matching on a collected gate voltage signal of the multi-chip IGBT module through a resistor divider formed by voltage-dividing resistors R₁ and R₂;
raising an output voltage V_{ge} of the resistor divider by a DC voltage E_{C} through a non-inverting adder, to ensure that an output signal V_{gep} of the non-inverting adder falls within an input voltage range allowed by a window comparator;
inputting the output signal V_{gep} of the non-inverting adder into the window comparator, comparing the output signal V_{gep} with input reference voltages V_{REF1} and V_{REF2}, respectively, and outputting corresponding comparison results Vₐ and V_{b}, V_{REF2} being the preset voltage V_{SET}; and
outputting the comparison results Vₐ and V_{b} to a logic sub-circuit through digital isolators U₄ and U₅, respectively, thereby respectively obtaining equivalent pulses during the turn-on and turn-off processes of the multi-chip IGBT module.

5. The method for monitoring chip open-circuit failure of a multi-chip IGBT module of claim 4, wherein obtaining, based on the captured equivalent pulses during the turn-on and turn-off processes of the multi-chip IGBT module, the digital pulse representing the gate-voltage pre-charging time t_{PG} specifically comprises steps of:
inputting equivalent pulses corresponding to output signals Vₐ and V_{b} of the window comparator into a logic AND gate U₇ to obtain a digital pulse V_{gg} represented by a pulse width; and
inputting the equivalent pulse corresponding to the output signal V_{b} of the window comparator into an RC delay circuit, and inputting an output signal of the RC delay circuit together with the equivalent pulse corresponding to V_{b} into a logic AND gate U₆ to obtain an enable signal OE.

6. The method for monitoring chip open-circuit failure of a multi-chip IGBT module of claim 5, wherein eliminating the pulse of the turn-off process in the digital pulse representing the gate-voltage pre-charging time t_{PG} and converting the obtained pulse into the analog voltage signal V_{PG} with the amplitude representing t_{PG} specifically comprises steps of:
inputting an output signal V_{gg} of the logic AND gate U₇ into a signal input terminal of a tri-state buffer U₈, and inputting an output signal OE of the logic AND gate U₆ into an enable terminal of the tri-state buffer U₈; and
inputting an output signal V_{buf} of the tri-state buffer U₈ into an RC integration circuit composed of a resistor R₈ and a capacitor C₃ to obtain the analog voltage signal V_{PG} with the amplitude representing t_{PG}.

7. The method for monitoring chip open-circuit failure of a multi-chip IGBT module of claim 6, wherein determining, based on the measured analog voltage signal V_{PG} and the failure threshold V_{REF3}, whether the multi-chip IGBT module has experienced chip open-circuit failure specifically comprises steps of:
causing the enable signal OE to pass through an RC delay circuit and a logic inverter U₁₀, thereby obtaining a clock signal CLK of a D flip-flop U₁₁;
inputting the output signal V_{PG} and the failure threshold V_{REF3} into a high-speed comparator U₉ for comparison;
inputting an output signal of the high-speed comparator U₉ into a data input terminal of the D flip-flop U₁₁;
outputting, by the D flip-flop U₁₁, a voltage signal V_{dia} characterizing a health state of a chip branch of the multi-chip IGBT module;
when an output voltage V_{dia} is at a low level, the multi-chip IGBT module being in a healthy state; and
when the output voltage V_{dia} is at a high level, the multi-chip IGBT module having experienced chip open-circuit failure.

8. A system for monitoring chip open-circuit failure of a multi-chip IGBT module, configured to perform the method of claim 1, wherein the system comprises a health-sensitive-parameter determination module, a measurement module, a failure-threshold determination module, and a diagnosis module, wherein the health-sensitive-parameter determination module is configured to determine a health-sensitive parameter for monitoring chip open-circuit failure of the multi-chip IGBT module, the health-sensitive parameter is determined as a gate-voltage pre-charging time t_{PG}, which is a time for a gate voltage of the multi-chip IGBT module to rise from 0 to a preset voltage V_{SET}, and the preset voltage V_{SET} is set below a flat-band voltage at a maximum operating voltage of the multi-chip IGBT module; the measurement module is configured to measure a value of the health-sensitive parameter of the multi-chip IGBT module and convert the value into an analog voltage signal V_{PG}; the failure-threshold determination module is configured to determine a failure threshold V_{REF3} of the analog voltage signal V_{PG} for determining that the multi-chip IGBT module has experienced chip open-circuit failure; and the diagnosis module is configured to determine, based on the measured analog voltage signal V_{PG} and the failure threshold V_{REF3}, whether the multi-chip IGBT module has experienced chip open-circuit failure.

9. The system for monitoring chip open-circuit failure of a multi-chip IGBT module of claim 8, wherein the measurement module employs a measurement circuit, and the measurement circuit comprises a signal-processing sub-circuit, a logic sub-circuit, and a signal-conversion sub-circuit;
the signal-processing sub-circuit comprises a resistor divider composed of voltage-dividing resistors R₁ and R₂, a non-inverting adder composed of a high-speed operational amplifier U₁, resistors R₃, R₄, R₅, and R₆, and a capacitor C₁, a window comparator composed of high-speed comparators U₂ and U₃, digital isolators U₄ and U₅, input reference voltages V_{REF1} and V_{REF2}, and a DC voltage E_{C}; the voltage-dividing resistors R₁ and R₂ are coupled in series between a gate G and an auxiliary emitter AE of the multi-chip IGBT module; a midpoint between the voltage-dividing resistors R₁ and R₂ is coupled to a non-inverting input terminal of the high-speed operational amplifier U₁ through the resistor R₄; the DC voltage E_{C} is coupled to the non-inverting input terminal of the high-speed operational amplifier U₁ through the resistor R₅; the resistor R₃ is coupled between an inverting input terminal of the high-speed operational amplifier U₁ and a reference ground; the resistor R₆ and the capacitor C₁ are coupled in parallel between the inverting input terminal and an output terminal of the high-speed operational amplifier U₁; the output terminal of the high-speed operational amplifier U₁ is respectively coupled to a non-inverting input terminal of the high-speed comparator U₂ and an inverting input terminal of the high-speed comparator U₃; the input reference voltages V_{REF1} and V_{REF2} are respectively coupled to an inverting input terminal of the high-speed comparator U₂ and a non-inverting input terminal of the high-speed comparator U₃; and outputs of the high-speed comparator U₂ and the high-speed comparator U₃ are respectively coupled to input terminals of the digital isolators U₄ and U₅;
the logic sub-circuit comprises an RC delay circuit composed of a resistor R₇ and a capacitor C₂ and two logic AND gates U₆ and U₇, the resistor R₇ and the capacitor C₂ are coupled in series between an output terminal of the digital isolator U₄ and a digital reference ground; input terminals of the logic AND gate U₆ are respectively coupled to a midpoint of the RC delay circuit and the output terminal of the digital isolator U₄; and input terminals of the logic AND gate U₇ are respectively coupled to the output terminal of the digital isolator U₄ and an output terminal of the digital isolator U₅; and
the signal-conversion sub-circuit comprises a tri-state buffer U₈ and an RC integration circuit composed of a resistor R₈ and a capacitor C₃; an enable terminal of the tri-state buffer U₈ is coupled to an output terminal of the logic AND gate U₆, a signal input terminal of the tri-state buffer U₈ is coupled to an output terminal of the logic AND gate U₇; the resistor R₈ and the capacitor C₃ are coupled in series between an output terminal of the tri-state buffer U₈ and the digital reference ground; and an output voltage at a series midpoint of the resistor R₈ and the capacitor C₃ is V_{PG} representing the gate-voltage pre-charging time.
